(19) United States
(12) Patent Application Publication
(10) Pub. No.: US 2011/0190980 A1
(43) Pub. Date: Aug. 4, 2011

(54) OCCUPANT DETECTION SYSTEM AND METHOD

(75) Inventor: Kevin D. Kincaid, Kokomo, IN (US)

(73) Assignee: DELPHI TECHNOLOGIES, INC., Troy, MI (US)

(21) Appl. No.: 12/700,243

(22) Filed: Feb. 4, 2010

(51) Int. Cl. G06F 7/00; G01R 27/26

(52) U.S. Cl. 701/36; 324/681

(57) ABSTRACT

An occupant detection system, a controller for an occupant detection system and a method of detecting an occupant. The presence or absence of the occupant varies the dielectric properties of an area proximate an electrode to influence the electrical impedance of the electrode. The electrode impedance is determined by determining electrical characteristics of a filter formed by a reference impedance device and the electrode. The pole frequency and absolute attenuation of the filter are determined based on a relative ratio of the excitation signal magnitude and the electrode signal magnitude, at two distinct frequencies. A lookup table may be used to determine the pole frequency and absolute attenuation based on the relative ratio, and thereby determine an occupant presence based on the electrode impedance.

### TECHNICAL FIELD OF INVENTION

The invention generally relates to vehicle passenger occupant detection, and more particularly relates to a system and method for determining a vehicle occupant proximate to an electrode.

### BACKGROUND OF INVENTION

It is known to selectively enable or disable a vehicle air bag or other occupant protection device based on the presence of an occupant in a seat. It has been proposed to place electrically conductive material in a vehicle seat to serve as an electrode for detecting the presence of an occupant in the seat. For example, U.S. Patent Application Publication No. 2009/0267622 A1, which is hereby incorporated herein by reference, describes a vehicle occupant detector that determines the presence of an occupant base on the electrode's electrical characteristics. The electrical characteristics may be determined by applying a sinusoidal excitation signal at various frequencies through a reference impedance device and comparing the electrode signal magnitude to the excitation signal magnitude. The presence of an occupant affects the electrical characteristics. Humidity and liquid moisture also affect the electrical characteristics and may affect the accuracy of determining an occupant.

### SUMMARY OF THE INVENTION

In accordance with one aspect of this invention, an occupant detection system is provided. The occupant detection system includes an electrode, a reference impedance device and a controller. The electrode is arranged proximate to an expected location of an occupant for sensing an occupant presence and an environmental condition proximate thereto. The electrode exhibits an electrode impedance corresponding to a network comprising a parallel arrangement of a capacitive part and a resistive part. The capacitive part has a capacitance value indicative of the occupant presence. The resistive part has a resistance value indicative of the environmental condition. The reference impedance device has a reference impedance value and is electrically coupled to the electrode to form a filter. The reference impedance device has a first terminal arranged to form a filter output and a second terminal arranged to form a filter input. The controller is configured to apply an excitation signal on the filter input and thereby generate an electrode signal on the filter output. The excitation signal has a first excitation magnitude at a first excitation frequency and a second excitation magnitude at a second excitation frequency distinct from the first frequency. The electrode signal has a first electrode magnitude generated in response to the excitation signal at the first excitation magnitude and the first excitation frequency, and a second electrode magnitude generated in response to the excitation signal at the second excitation magnitude and the second excitation frequency. The controller is further configured to determine the capacitance value based on the reference impedance value, the excitation signal, and the electrode signal, and thereby determine the occupant presence.

In another aspect of the present invention, a controller in an occupant detection system is provided. The occupant detection system has an electrode arranged proximate to an expected location of an occupant for sensing an occupant presence and an environmental condition proximate thereto. The electrode exhibits an electrode impedance corresponding to a network comprising a parallel arrangement of a capacitive part and a resistive part, wherein the capacitive part has a capacitance value indicative of the occupant presence, and the resistive part has a resistance value indicative of the environmental condition. The controller includes a reference impedance device, a signal generator, a voltage detector, and a processor. The reference impedance device has a reference impedance value and is coupled to the electrode to form a filter. The reference impedance device includes a first terminal arranged to form a filter output and a second terminal arranged to form a filter input. The signal generator is configured to apply an excitation signal on the filter input and thereby generate an electrode signal on the filter output. The excitation signal has a first excitation magnitude at a first excitation frequency and a second excitation magnitude at a second excitation frequency distinct from the first frequency. The voltage detector is configured to determine a first electrode magnitude generated in response to the excitation signal at the first excitation magnitude and the first excitation frequency, and determine a second electrode magnitude generated in response to the excitation signal at the second excitation magnitude and the second excitation frequency. The processor is configured to determine the capacitance value value based on the reference impedance value, the excitation signal, and the electrode signal, and thereby determine the occupant presence.

In yet another aspect of the present invention, a method for detecting a vehicle occupant is provided. The method includes arranging an electrode proximate to an expected location of an occupant for sensing an occupant presence and an environmental condition proximate thereto. The electrode exhibits an electrode impedance corresponding to a network comprising a parallel arrangement of a capacitive part and a resistive part. The capacitive part has a capacitance value indicative of the occupant presence. The resistive part has a resistance value indicative of the environmental condition. The method includes coupling a reference impedance device to the electrode to form a filter. The reference impedance device has a first terminal arranged to form a filter output and a second terminal arranged to form a filter input. The method includes applying an excitation signal on the filter input. The excitation signal has a first excitation magnitude at a first excitation frequency and a second excitation magnitude at a second excitation frequency distinct from the first frequency. The method includes generating an electrode signal on the filter output in response to the excitation signal. The excitation signal has a first electrode magnitude generated in response to the excitation signal at the first excitation magnitude and the first excitation frequency, and a second electrode magnitude generated in response to the excitation signal at the second excitation magnitude and the second excitation frequency. The method includes determining the capacitance value based on the reference impedance value, the excitation signal, and the electrode signal, thereby determining the occupant presence.

Further features and advantages of the invention will appear more clearly on a reading of the following detail description of the preferred embodiment of the invention, which is given by way of non-limiting example only and with reference to the accompanying drawings.

### BRIEF DESCRIPTION OF DRAWINGS

The present invention will now be described, by way of example with reference to the accompanying drawings, in which:

FIG. 1 block diagram of an occupant detection system, according to one embodiment;

FIG. 2 is a perspective view of a seat assembly incorporating the occupant detection system shown in FIG. 1;

FIG. 3 is a block/circuit diagram illustrating one embodiment the occupant detection system shown in FIG. 1;

FIG. 4 is a graph of an exemplary frequency response characteristic of a signal detected with the circuit shown in FIG. 3; and

FIG. 5 is a flow chart illustrating a method to determine presence of an occupant residing in the seat assembly shown in FIG. 2.

### DETAILED DESCRIPTION OF INVENTION

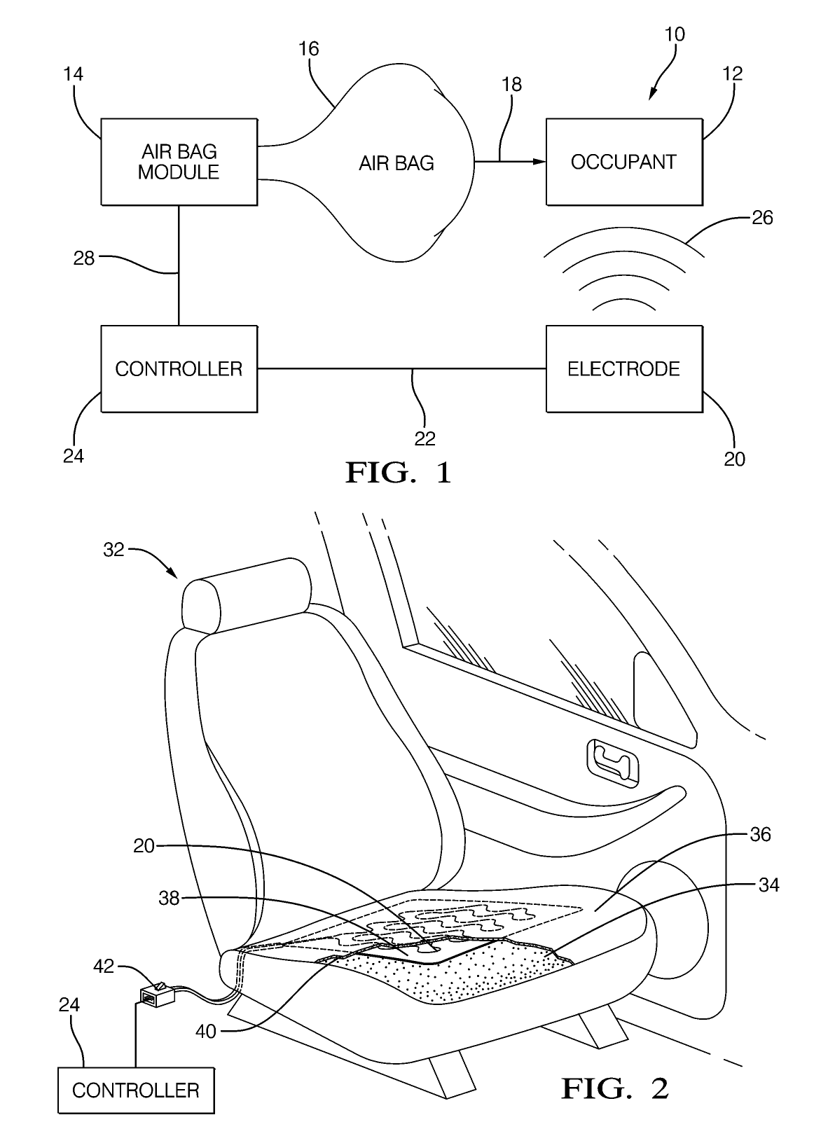

In accordance with an embodiment of an occupant detector, FIG. 1 illustrates an occupant detection system 10 for determining the presence of an occupant 12 seated in a vehicle seat assembly 32 as seen in FIG. 2. The occupant 12 may be an adult or an infant in a child seat according to one embodiment. The occupant detection system 10 may include an air bag module 14 that deploys an air bag 16 as indicated by an arrow 18 to restrain or protect the occupant 12 in the event of a vehicle collision. Determining an occupant presence in the vehicle seat assembly 32 may include characterizing the occupant (e.g., adult versus infant) which may be useful for enabling or disabling the air bag module 14 or other passenger protection device in the vehicle. It is advantageous to disable the air bag module 14 if the vehicle seat is empty or occupied by an infant in a child seat so the air bag 16 is not unnecessarily deployed. The air bag module 14 may receive an activation signal 28 from a controller 24 to arm the air bag module 14 so that a signal from a collision detection system (not shown) can deploy the air bag 16. It should be appreciated that the occupant detection system 10 may be used for other vehicle functions such as activating a seat belt warning if the seat belt is not properly employed.

The occupant detection system 10 includes an electrode 20 arranged proximate to or adjacent to an expected location of the occupant 12 for sensing an occupant presence and/or an environmental condition proximate thereto. While not subscribing to any particular theory, it has been observed that when an electrode signal 22 is applied to the electrode 20, an electrode impedance is exhibited by the electrode 20 that varies correspondingly with the presence or absence of an occupant 12 on or near the seat assembly 32. It has been suggested that the electrode signal 22 generates an electric field 26 in response to the electrode signal 22, thereby causing the electrode 20 to provide or exhibit the electrode impedance. It has also been observed that environmental conditions such as humidity, temperature, and wear of the material used in the vehicle seat assembly 32 also influence the electrode impedance.

FIG. 2 illustrates an exemplary, non-limiting embodiment of an electrode 20 arranged in the vehicle seat assembly 32 suitable for use by the occupant detection system 10 to determine the presence of the occupant 12 (not shown in FIG. 2) on or near the seat assembly 32. The seat assembly 32 is illustrated as being in a vehicle passenger compartment according to one embodiment, but could be used in any kind of vehicle, such as an airplane. The seat assembly 32 has a seat cushion 34 for providing a seating surface 36 to support the occupant 12. Seat cushion 34 is suitably made of foam having characteristics suitable for seating use. Adjacent the seating surface 36 is an exemplary embodiment of the electrode 20 in the form of a wire coupled to a mat 38 that simplifies arranging the electrode 20 in seat assembly 32. The electrode 20 can be made of a variety of electrically conductive materials suitable for use adjacent the seating surface 36. Exemplary materials for forming the electrode 20 include metal wire, conductive fiber, conductive ink, metal foil, and metal ribbon. The cushion 34 is covered with covering 40 to protect the cushion 34 and the electrode 20, and to make the appearance of seat assembly 30 attractive. The electrode 20 may be arranged to be located adjacent or proximate to the seating surface 36. It has been observed that such an arrangement improves sensitivity and accuracy for detecting an occupant near seating surface 36 by determining the electrode impedance. The electrode 20 may be coupled to the controller 24 by a connector 42 so electrode 20 can be readily connected to the controller 24.

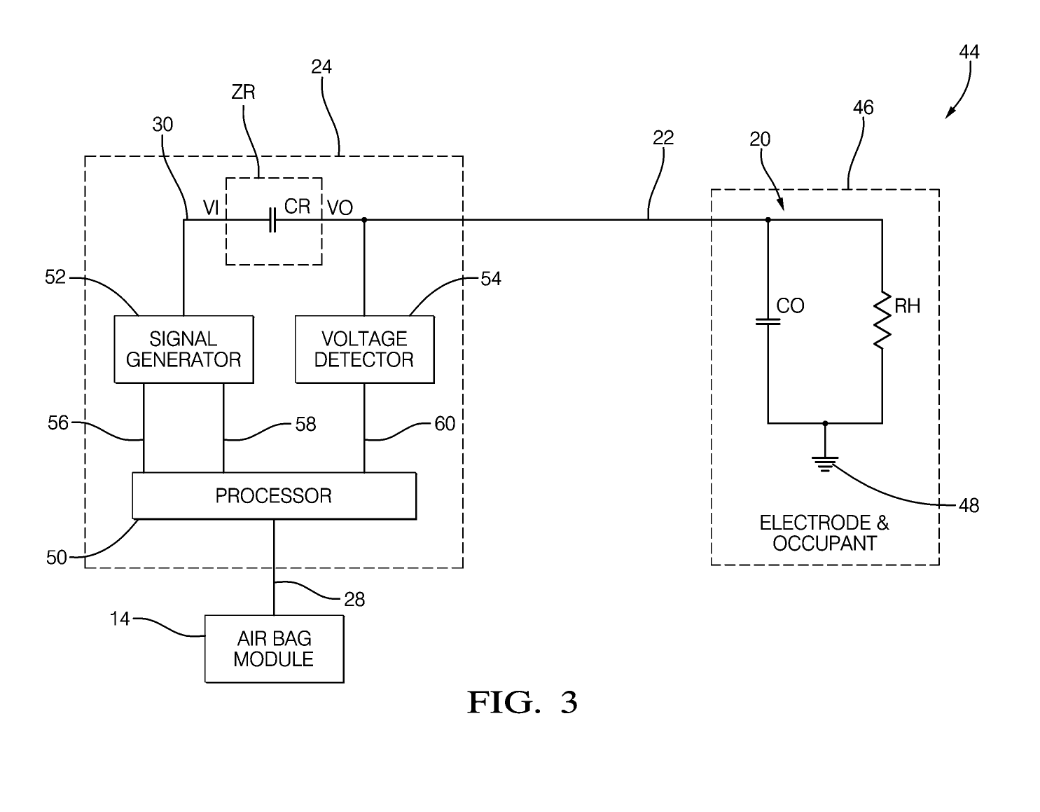

FIG. 3 illustrates an exemplary embodiment of a circuit diagram 44 for describing the operation of the occupant detection system 10. It has been discovered that variation of electrode impedance exhibited by the electrode 20 due to an occupant or an environmental condition may be modeled or illustrated by a network 46 comprising a parallel arrangement of a capacitive part CO and a resistive part RH. It has also been discovered that the capacitive part CO has a capacitance value that is indicative of an occupant presence, and the resistive part RH has a resistance value that is indicative of an environmental condition. For descriptive illustration purposes and not subscribing to any particular theory, the capacitive part CO may be described as corresponding to two spaced apart electrically conductive plates with material having a dielectric constant occupying the space between the plates. The dielectric constant of the material influences the capacitance value of the capacitive part CO. One plate of the capacitive part CO corresponds to the electrode 20. The other plate of capacitive part CO then corresponds to the frame and body of the vehicle surrounding the occupant 12 and is shown as being connected to a reference ground 48. It follows that the dielectric material between the plates of capacitive part CO corresponds at least in part to the occupant 12.

It has been observed that when the seat is empty, the capacitance value of the capacitive part CO is lower than the capacitance value when the seat is occupied. The presence of a large adult versus a small child, or the absence of an occupant may vary the dielectric constant of the dielectric material between the plates and thereby varies the capacitance value of capacitive part CO. Furthermore, the area of the electrode 20 corresponds to the area of the capacitive part CO, so changing the area of the electrode may vary the capacitance value for the same occupant. A typical capacitance value for the exemplary empty seat assembly 32 illustrated in FIG. 2 is about 100 pF. When an adult occupies the seat assembly 32, the capacitive term may increases as much as 900 pF. As such, the electrode 20 has an electrode impedance that is indicative of occupant presence and occupant size.

The network 46 also illustrates a resistive part RH in parallel with capacitive part CO that suggests a resistive path for direct current that corresponds with dielectric leakage of a capacitor. The value of resistive part RH may be dependent on the materials used to make cushion 34 and seat cover 40, and on other environmental conditions such as relative humidity, temperature, or changes due to wear and breakdown of the materials used to form the seat assembly 32. It has been observed that the resistance value of resistive part RH decreases as the humidity in and around the seat assembly 32 increases, or if liquid moisture is present in or on the seat assembly 32. A typical resistance value of resistive part RH for a dry seat assembly 32 corresponding to a resistive portion of the electrode impedance is greater than 1.0MΩ (1 mega Ohms). If the humidity level is high, the resistive part RH may be below 100 kΩ (100 kilo Ohms). If the seat is wet due to a spilled drink for example, the resistive part RH may be below 10 kΩ.

FIG. 3 further illustrates an embodiment of a controller 24 that includes a reference impedance device ZR having a reference impedance value. In this embodiment, the reference impedance device ZR is electrically coupled to the electrode 20 to form a filter generally having electrical characteristics that are dependent on the reference impedance value and the electrode impedance value. The reference impedance device ZR has a first terminal connected to the electrode 20 that is designated to be a filter output VO of the filter, and a second terminal connected to a signal generator 52 that is designated to be a filter input VI of the filter. The filter characteristics may be determined by comparing an excitation signal 30 from the signal generator 52 to an electrode signal 22 measured by the voltage detector 54. In one embodiment, the excitation signal may be in the form of a sinusoidal waveform. A sinusoidal waveform is advantageous because the formulas for determining the capacitance value of the capacitive part CO and the resistance value of the resistive part RH are typically simpler for sinusoidal waveforms.

The controller 24 has a signal generator 52 that is configured to apply an excitation signal 30 on the filter input VI to generate an electrode signal 22 on the filter output VO in response to the excitation signal 30. The signal generator 52 in this embodiment receives a frequency control signal 56 and a magnitude control sign 58 from a processor 50 to generate the excitation signal 30 characterized as having an excitation signal magnitude at an excitation signal frequency. The excitation signal 30 is coupled through reference impedance device ZR and causes an electrode signal 22 to arise on the filter output VO. The filter output VO may be characterized as having an electrode signal magnitude at an electrode signal frequency. In this embodiment, a voltage detector 54 is connected to the filter output VO to receive the electrode signal 22. The voltage detector 54 may be configured to determine an electrode signal magnitude and send a magnitude signal 60 to processor 50. Because the electrode impedance includes reactive components such as the capacitive part CO, the excitation signal and electrode signal will differ in both phase and magnitude when the excitation signal is a sinusoidal waveform.

The electrode impedance may be determined based on a first excitation signal frequency, a first excitation signal magnitude, a first electrode magnitude, a second excitation signal frequency, a second excitation signal magnitude, and a second electrode signal magnitude. It is advantageous to determine the electrode impedance determination based on the magnitudes of various signals because measuring magnitude is typically simpler than measuring a phase difference between an excitation signal and an electrode signal. The processor 50, the signal generator 52, and the voltage detector 54 are shown as separate blocks for the purpose of explanation. However, it should be understood that other control circuitry or devices that incorporate the functions of the processor 50, the signal generator 52, and the voltage detector 54 into a single device or alternative devices may be employed.

In one embodiment the reference impedance device ZR is a reference capacitor CR. It is advantageous for the reference impedance device ZR to use a capacitor since capacitors having stable capacitance values over time and temperature are readily available. In other embodiments, the reference impedance device ZR may include a resistor in parallel or in series with a capacitor, or may include an inductor. In this embodiment, the arrangement of the reference capacitor CR with the capacitive part CO and the resistive part RH forms a high pass filter that may be characterized as having a pole frequency FP, a fixed attenuation AF and an absolute attenuation AA. The attenuation of the filter, that is the filter output VO divided by the filter input VI, for an excitation signal having a sinusoidal waveform and an excitation frequency FE may be defined by the following equation 1:

VO/VI=[CR/(CR+CO)]*[2π*FE*RH(CR+CO)]/[((2π*FE*RH(CR+CO))̂2)+1)̂0.5] Equation 1

As used herein, the value of the fixed attenuation AF is the portion of the transfer function that is independent of excitation signal frequency FE, and the value of the absolute attenuation AA is the portion of the transfer function that is dependent of excitation signal frequency FE. The pole frequency FP may be generally described as a corner frequency of the high pass filter arrangement. In one embodiment, the fixed attenuation AF, absolute attenuation AA, and the pole frequency FP may be expressed by the following equations 2-4, respectively.

AF=[CR/(CR+CO)] Equation 2

AA=[2π*FE*RH(CR+CO)]/[((2π*FE*RH(CR+CO))̂2)+1)̂0.5] Equation 3

FP=1/(2π*RH*(CR+CO)) Equation 4

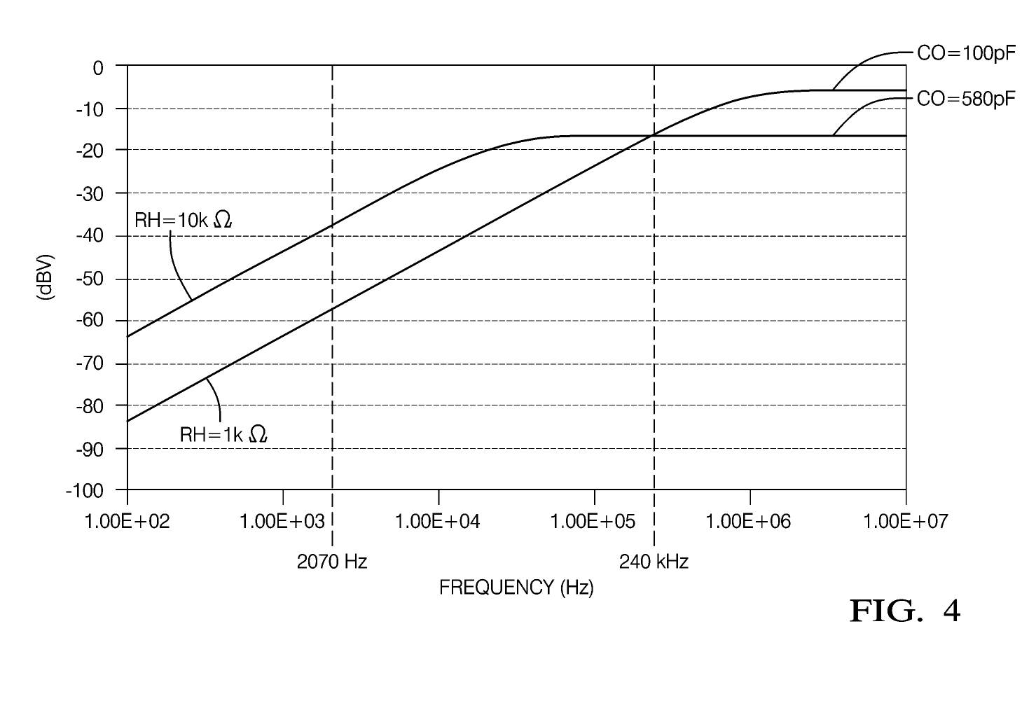

FIG. 4 shows a graph of the attenuation characteristics for an embodiment of the occupant detection system 10, wherein the reference capacitor CR is 100 pF and various values of the capacitive part CO and the resistive part RH are indicated on the graph. The x-axis is the excitation frequency in Hertz (Hz). The y-axis is the attenuation of the filter output VO with respect to a filter input VI in decibels (dBV=−20*log(VO/VI)). For this embodiment, at frequencies greater than 1 MHz (1*10⁶ Hz) the attenuation is predominately determined by the value of the reference capacitor CR and the capacitive part CO. However, it has been determined through empirical testing that applying an excitation signal having an excitation frequency around 1 MHz may lead to excessive radiated emissions. It has been suggested that the excitation frequency be limited to about 240 kHz (240*10³ Hz). As can be seen, the filter attenuation when the excitation frequency is around 240 kHz cannot readily distinguish an electrode impedance based on a capacitive part CO of 100 pF and resistive part RH of 1 kOhm and indicative of a empty/wet seat from an electrode impedance based on a capacitive part CO of 580 pF and resistive part RH of 10 kOhm and indicative of a presence of an adult at high humidity. It has been discovered that if the attenuation of the filter is determined at two distinct frequencies, then the capacitance value of the capacitive part CO and the resistance value of the resistive part RH may be determined.

As such, the signal generator 52 in one embodiment outputs the excitation signal 30 having a first excitation magnitude at a first excitation frequency F1 and a second excitation magnitude at a second excitation frequency F2 distinct from the first frequency F1. It follows that the electrode signal 22 has a first electrode magnitude generated in response to the first excitation magnitude at the first excitation frequency F1 and, a second electrode magnitude generated in response to the second excitation magnitude at the second excitation frequency F2. The controller 24 may be configured to determine the capacitance value of the capacitive part CO and determine the resistance value of the resistive part RH based on the reference impedance value of the reference impedance device ZR, the first excitation magnitude, the second excitation magnitude, the first electrode magnitude, and the second electrode magnitude, and thereby determine the occupant presence and the environmental condition.

In another embodiment, the controller 24 may determine the capacitance value of the capacitive part CO and the resistance value of the resistive part RH by determining the pole frequency FP and the absolute attenuation AA of the filter. The controller 24 may determine the pole frequency FP and the absolute attenuation AA based on a relative ratio RR of a first attenuation ratio at the first excitation frequency F1 over a second attenuation ratio at the second excitation frequency F2. As used herein, the first attenuation ratio is the ratio of the first electrode magnitude at filter output VO over the first excitation magnitude at the filter input VI, and the second attenuation ratio is the ratio of the second electrode magnitude at the filter output VO over the second excitation magnitude at the filter input VI. By calculating the relative ratio RR and knowing the first excitation frequency F1 and the second excitation frequency F2, the capacitance value of the capacitive part CO and the resistance value of the resistive part RH can be determined using Equations 1-4 above. If the processor 50 has sophisticated math processing capability, such as found in a personal computer, the determination of the capacitance value of the capacitive part CO and the resistance value of the resistive part RH may readily be performed by direct calculation. However, if the processor 50 is based on a relatively small single chip microprocessor such as what may be used by a vehicle occupant detection system, mathematical operations such as calculating the square root of a number may become burdensome. As such, one embodiment of the processor 50 may include a lookup table for determining the pole frequency FP and the absolute attenuation AA based on the relative ratio RR.

The determination of the capacitance value of the capacitive part CO and the resistance value of the resistive part RH may be demonstrated by the following example. This example assumes that the reference capacitor CS is 100 pF and that the signal generator 32 outputs a first excitation frequency F1 of 2070 Hz and a second excitation frequency F2 of 240 kHz in accordance with the frequency control signal 56. Also, the example assumes that both the first excitation signal magnitude and the second excitation magnitude are set at 1.00 Volt by the magnitude control signal 58. If the first electrode magnitude arising from the first excitation frequency F1 of 2070 Hz is measured by voltage detector 54 as 0.013002 Volts and the second electrode magnitude arising from the first excitation frequency F2 of 240 kHz is measured by voltage detector 54 as 0.474592 Volts, then the relative ratio RR is about 0.02739575.

Table 1 shown below is a portion of an exemplary lookup table. Such a table may be prepared by selecting a pole frequency FP and then using Equation 1 to calculate the relative ratio RR and using Equations 3 and 4 to calculate the absolute attenuation AA. It should be understood that Table 1 represents only a select portion of one example of a lookup table necessary for the occupant detection system 10 to determine the presence an occupant 12. The range of pole frequency FP included in a complete lookup table would be determined by the expected range of electrode impedance presented by an electrode 20 as part of a vehicle seat assembly 32. The resolution of the table may be determined by the degree of accuracy desired.

TABLE 1

| Relative Ratio RR | Pole Frequency FP (Hz) | Absolute Attn. AA |
|---|---|---|
| 0.027396825 | 79574 | 0.9491875 |
| 0.027396515 | 79575 | 0.9491863 |
| 0.027396205 | 79576 | 0.9491852 |
| 0.027395895 | 79577 | 0.9491840 |
| 0.027395585 | 79578 | 0.9491828 |
| 0.027395275 | 79579 | 0.9491816 |
| 0.027394966 | 79580 | 0.9491804 |

For the relative ratio RR of 0.02739575, a pole frequency FP of 79577 Hz and an absolute attenuation AA of 0.9491834 can be linearly interpolated using the table entries for the relative ratios RR 0.027395895 and 0.027395585. Linear interpolation may provide suitable accuracy and may be readily performed a microprocessor. If a greater degree of accuracy is desired, a non-linear interpolation using more than two data points may be used, or the resolution of the table may be increased. Once the values of the pole frequency FP and the absolute attenuation AA are known, Equations 1-4 may be used to calculate the capacitance value of the capacitive part CO to be equal to about 100 pF, and the resistance value of the resistive part RH to be equal to about 10 kΩ (10,000 Ohms).

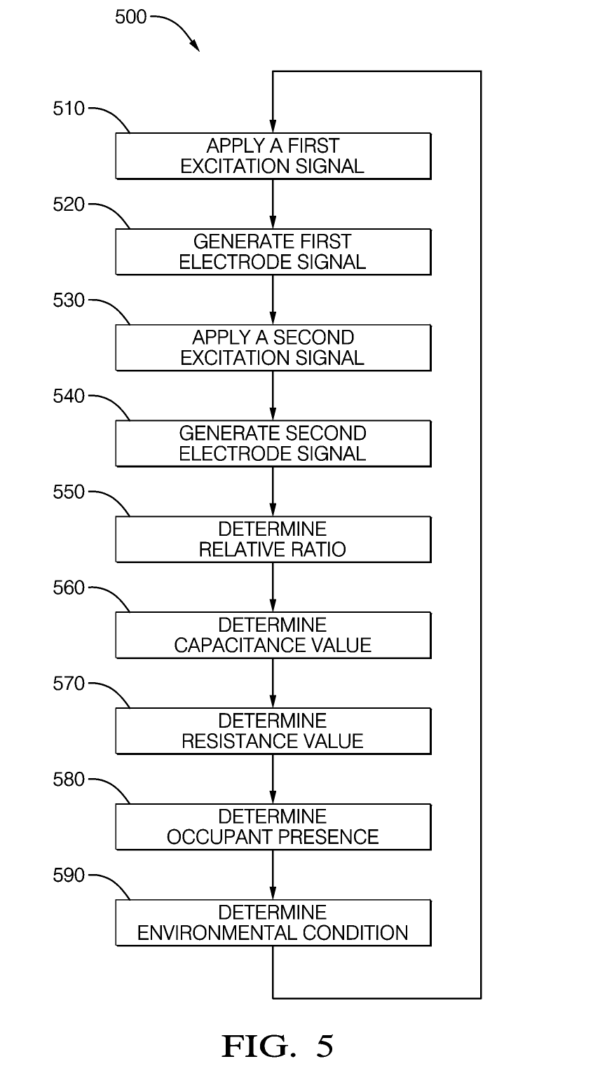

FIG. 5 illustrates a method or routine 500 of an embodiment of a method for detecting a vehicle occupant 12 in a vehicle seat assembly 32. The method may include arranging an electrode 20 proximate to an expected location of an occupant, such as the vehicle seat assembly. The electrode 20 may be useful for sensing an occupant presence and an environmental condition proximate thereto. While not subscribing to any particular theory, the electrode 20 may exhibit an electrode impedance corresponding to a network comprising a parallel arrangement of a capacitive part CO and a resistive part RH. The capacitive part CO may have a capacitance value indicative of the occupant presence. The resistive part RH may have a resistance value indicative of the environmental condition. The method may also include coupling a reference impedance device ZR to the electrode 30 to form a filter. The reference impedance device may have a first terminal arranged with the electrode to form a filter output VO, and a second terminal arranged to form a filter input VI. In one embodiment the reference impedance device ZR is a capacitor CR, so the filter may be characterized as a high pass filter having a pole frequency FP and an absolute attenuation AA.

At step 510 of method 500, a controller 24 applies a first excitation signal to the filter input VI that may be characterized as having a first excitation signal magnitude and a first excitation signal frequency F1. At step 520, a first electrode signal is generated at the filter output VO in response to the application of the first excitation signal. The first electrode signal may be characterized as having a first electrode signal magnitude and a first electrode signal frequency corresponding to the first excitation signal frequency F1. The first electrode signal magnitude is dependent on the first excitation signal magnitude, the first excitation signal frequency F1, the reference impedance ZR, and the electrode impedance.

At step 530 of method 500, the controller 24 applies a second excitation signal to the filter input VI. The second excitation signal may be characterized as having a second excitation signal magnitude and a second excitation signal frequency F2. At step 540, a second electrode signal is generated at the filter output VO in response to the application of the second excitation signal. The second electrode signal may be characterized as having a second electrode signal magnitude and a second electrode signal frequency corresponding to the second excitation signal frequency F2. The second electrode signal magnitude is dependent on the second excitation signal magnitude, the second excitation signal frequency F2, the reference impedance ZR, and the electrode impedance.

At step 550 of method 500, the controller 24 determines a relative ratio RR based on the filter attenuation at the two excitation signal frequencies F1 and F2. The filter attenuation at a given excitation signal frequency is based on the electrode signal magnitude divided by the excitation signal magnitude. The relative ratio RR is determined based on the ratio of the filter attenuation and may be expressed as [VO(F1)/VI(F1)]/[VO(F2)/VI(F2)] according to one embodiment. In one embodiment, the first excitation signal frequency F1 is less than the second excitation frequency F2. However, it should be understood that reversing the values of the first and second frequencies may also be used to calculate the relative ratio RR if the equations or lookup table used in the determination of the table values are adjusted appropriately. The relative ratio RR may be used with Equations 1-4 or a lookup table to determine the pole frequency FP and the absolute attenuation AA.

At step 560, the controller may use the pole frequency FP and the absolute attenuation AA to determine capacitance value for capacitive part CO. At step 570, once the capacitive part CO and the pole frequency FP are known, Equation 4 may be used to determine a resistance value for the resistive part RH. If the resistance value of resistive part RH is too low, it may be an indication that the seat is wet. A wet seat may be a condition that may render the determination of the capacitive part CO unreliable or in need of compensation. If the determination of the capacitive part CO is characterized as being unreliable then the controller 24 may output a warning signal (not shown) to the occupant 12, or output a warning signal to a collision detection system that determines when to deploy a device such as an airbag 16.

If the capacitance value is determined to be reliable, then at step 580, controller 24 uses the capacitance value of the capacitive part CO to determine an occupant presence. At step 590, the controller 24 may also determine an environmental condition such as a relative humidity level. Determining the relative humidity may be useful for compensating the determination of an occupant presence base on the capacitance value of the capacitive part CO.

Accordingly, an occupant detection system 10, a controller 24 for the occupant detection system 10 and a method of detecting an occupant 12 is provided. The presence or absence of the occupant 12 varies the dielectric properties of an area proximate to an electrode 20 generating an electric field 26, and thereby influences the electrical impedance of the electrode 20. The electrode impedance may be characterized by a network formed by a parallel combination of a capacitive part CO and a resistive part RH. The capacitance value of the capacitive part CO may be used to determine the presence of an occupant. The resistance value of the resistive part RH may be used to determine an environmental condition such as humidity or a wet seat. The resistance value of the resistance part RH may also be used to compensate the determination of the occupant presence based on the capacitance value of the capacitive part CO. The capacitance value of the capacitive part CO and the resistance value of the resistive part RH may be determined by measuring frequency response characteristics of a filter formed by the electrode 20 and a reference impedance ZR. In one embodiment, the filter is characterized by measuring the magnitudes of signals present at the filter input VI and the filter output VO at two distinct frequencies. It is advantageous for the occupant detection system 10 to rely on signal magnitudes since magnitudes are readily measured using inexpensive electrical devices. An occupant is then determined based on the capacitance value. The resistance value serves to indicate an environmental condition such as humidity, and provide an indication of the confidence or signal to noise ratio of the occupant determination based on the capacitance value.

While this invention has been described in terms of the preferred embodiments thereof, it is not intended to be so limited, but rather only to the extent set forth in the claims that follow.

We claim:

1. A vehicle occupant detection system comprising:
an electrode arranged proximate to an expected location of an occupant for sensing an occupant presence and an environmental condition proximate thereto, said electrode exhibiting an electrode impedance corresponding to a network comprising a parallel arrangement of a capacitive part and a resistive part, said capacitive part having a capacitance value indicative of the occupant presence, said resistive part having a resistance value indicative of the environmental condition;
a reference impedance device having a reference impedance value and electrically coupled to the electrode to form a filter, said reference impedance device comprising a first terminal arranged to form a filter output and a second terminal arranged to form a filter input; and
a controller configured to apply an excitation signal on the filter input and thereby generate an electrode signal on the filter output in response to the excitation signal, said excitation signal having a first excitation magnitude at a first excitation frequency and a second excitation magnitude at a second excitation frequency distinct from the first frequency, said electrode signal having a first electrode magnitude generated in response to the excitation signal at the first excitation magnitude and the first excitation frequency, and a second electrode magnitude generated in response to the excitation signal at the second excitation magnitude and the second excitation frequency, said controller further configured to determine the capacitance value based on the reference impedance value, the excitation signal, and the electrode signal, and thereby determine the occupant presence.

2. The occupant detection system in accordance with claim 1, wherein the controller is further configured to determine the resistance value based on the reference impedance value, the excitation signal, and the electrode signal, and thereby determine the environmental condition.

3. The occupant detection system in accordance with claim 2, wherein the environmental condition comprises humidity.

4. The occupant detection system in accordance with claim 2, wherein the reference impedance device comprises a capacitor, whereby the filter is a high pass filter characterized as having a pole frequency and an absolute attenuation.

5. The occupant detection system in accordance with claim 4, wherein the controller is further configured to determine the capacitance value and the resistance value based on a determination of the pole frequency and the absolute attenuation.

6. The occupant detection system in accordance with claim 5, wherein the controller is further configured to determine the pole frequency and the absolute attenuation based on a relative ratio of a first attenuation ratio at the first excitation frequency to a second attenuation ratio at the second excitation frequency.

7. The occupant detection system in accordance with claim 6, wherein the controller is further configured to determine the pole frequency and the absolute attenuation based on a look-up table comprising a pole frequency value and an absolute attenuation value corresponding to the relative ratio value.

8. The occupant detection system in accordance with claim 1, wherein the electrode is adjacent a seating surface of a vehicle seat to sense the occupant seated in the vehicle seat.

9. The occupant detection system in accordance with claim 1, said system further comprising an air bag module receiving an activation signal from the controller, wherein said activation signal is based on the determined occupant presence.

10. A controller in a vehicle occupant detection system comprising an electrode arranged proximate to an expected location of an occupant for sensing an occupant presence and an environmental condition proximate thereto, said electrode exhibiting an electrode impedance corresponding to a network comprising a parallel arrangement of a capacitive part and a resistive part, said capacitive part having a capacitance value indicative of the occupant presence, said resistive part having a resistance value indicative of the environmental condition, said controller comprising:
a reference impedance device having a reference impedance value and coupled to the electrode to form a filter, said reference impedance device comprising a first terminal arranged to form a filter output and a second terminal arranged to form a filter input;
a signal generator configured to apply an excitation signal on the filter input and thereby generate an electrode signal on the filter output in response to the excitation signal, said excitation signal having a first excitation magnitude at a first excitation frequency and a second excitation magnitude at a second excitation frequency distinct from the first frequency;
a voltage detector configured to determine a first electrode magnitude generated in response to the excitation signal at the first excitation magnitude and the first excitation frequency, and determine a second electrode magnitude generated in response to the excitation signal at the second excitation magnitude and the second excitation frequency; and
a processor configured to determine the capacitance value based on the reference impedance value, the excitation signal, and the electrode signal, and thereby determine the occupant presence.

11. The controller in accordance with claim 10, wherein the processor is further configured to determine the resistance value based on the reference impedance value, the excitation signal, and the electrode signal, and thereby determine the environmental condition.

12. The controller in accordance with claim 11, wherein the reference impedance device comprises a capacitor, whereby the filter is a high pass filter characterized as having a pole frequency and an absolute attenuation, wherein the processor is further configured to determine the pole frequency and determine the absolute attenuation based on a relative ratio of a first attenuation ratio at the first excitation frequency to a second attenuation ratio at the second excitation frequency, and determine the capacitance value and determine the resistance value based on the pole frequency and absolute attenuation.

13. A method for detecting a vehicle occupant comprising the steps of:
arranging an electrode proximate to an expected location of an occupant for sensing an occupant presence and an environmental condition proximate thereto, said electrode exhibiting an electrode impedance corresponding to a network comprising a parallel arrangement of a capacitive part and a resistive part, said capacitive part having a capacitance value indicative of the occupant presence, said resistive part having a resistance value indicative of the environmental condition;
coupling a reference impedance device to the electrode to form a filter, said reference impedance device comprising a first terminal arranged to form a filter output and a second terminal arranged to form a filter input;
applying an excitation signal on the filter input, said excitation signal having a first excitation magnitude at a first excitation frequency and a second excitation magnitude at a second excitation frequency distinct from the first frequency;
generating an electrode signal on the filter output in response to the excitation signal, said excitation signal having a first electrode magnitude generated in response to the excitation signal at the first excitation magnitude and the first excitation frequency, and a second electrode magnitude generated in response to the excitation signal at the second excitation magnitude and the second excitation frequency; and
determining the capacitance value based on the reference impedance value, the excitation signal, and the electrode signal, thereby determining the occupant presence.

14. The method in accordance with claim 13, further comprising the step of determining the resistance value based on the reference impedance value, the excitation signal, and the electrode signal, thereby determining the environmental condition.

15. The method in accordance with claim 14, wherein the environmental condition determined comprises humidity.

16. The method in accordance with claim 14, wherein the reference impedance device comprises a capacitor, whereby the filter is a high pass filter is characterized as having a pole frequency and an absolute attenuation.

17. The method in accordance with claim 16, wherein the step of determining the capacitance value and the resistance value includes determining the pole frequency and the absolute attenuation of the filter.

18. The method in accordance with claim 17, wherein the step of determining the pole frequency and the absolute attenuation includes determining a relative ratio of a first attenuation ratio at the first excitation frequency to a second attenuation ratio at the second excitation frequency.

19. The method in accordance with claim 18, wherein the step of determining the pole frequency and the absolute attenuation includes determining a look-up table comprising a pole frequency value and an absolute attenuation value corresponding to the relative ratio value.

20. The method in accordance with claim 13, further comprising the step of activating an air bag module based on determining an occupant presence.
